(19) United States
(12) Patent Application Publication
(10) Pub. No.: US 2014/0341534 A1
(43) Pub. Date: Nov. 20, 2014

(54) Digital postcard

(71) Applicant: Ailyn Margarita Gonzalez, Bronx, NY (US)

(72) Inventor: Ailyn Margarita Gonzalez, Bronx, NY (US)

(21) Appl. No.: 13/999,438

(22) Filed: Feb. 26, 2014

Related U.S. Application Data
(60) Provisional application No. 61/772,555, filed on Mar. 5, 2013.

(51) Int. Cl. H04N 5/93; G11B 33/06; G11B 33/02; H05K 5/00; H04N 5/907

(52) U.S. Cl. CPC H04N 5/93; H05K 5/0086; H04N 5/907; G11B 33/025; G11B 33/06
USPC 386/230

(57) ABSTRACT

The digital postcard is a hand held device used to transmit messages via color monitor display eliciting previously recorded digital media and/or audio files. The digital postcard contains simplistic navigational buttons used for directing the viewing of media and/or audio files. The digital postcard is light, customizable and hand-held for easy customer distribution and interaction. Media and audio files can be updated using SD Card or USB loading options; consequently, rendering the device updatable and multiuseable.

### BACKGROUND OF THE INVENTION

1. Field of the Invention

This invention relates generally to a digital postcard; specifically, it relates to a digital postcard providing a postcard-sized electronic device for conveying digitally recorded intimate messages to person(s) of choice.

2. Description of the Prior Art

While post cards provide a cheap and effective way of communicating intimate messages to person(s) of choice, the popularity of this tradition has been eclipsed with the rise of increasing use of computers; specifically, internet sharing. A simple email is capable of furbishing highly graphic messages, which is more than a standard issued postcard is capable of illustrating. In addition, emails can contain video clips, sound files as and multiple forms of multimedia elements that can enrich the experience of receiving intimate messages. Most standard post cards are limited to space, possible recorded sound bites, and basic ink printed designs—they lack personalization that a digital display can provide. The digital postcard will bridge the gap by providing the same capabilities an email can provide with the personalized hand held experience that standard postcards provide.

### BRIEF DESCRIPTION OF THE DRAWINGS

FIGS. 1a, 1b, 2a and 2b are perspective views illustrating a digital postcard device(s), constructed in accordance with the present invention.

### DETAILED DESCRIPTION OF THE PREFERRED EMBODIMENTS

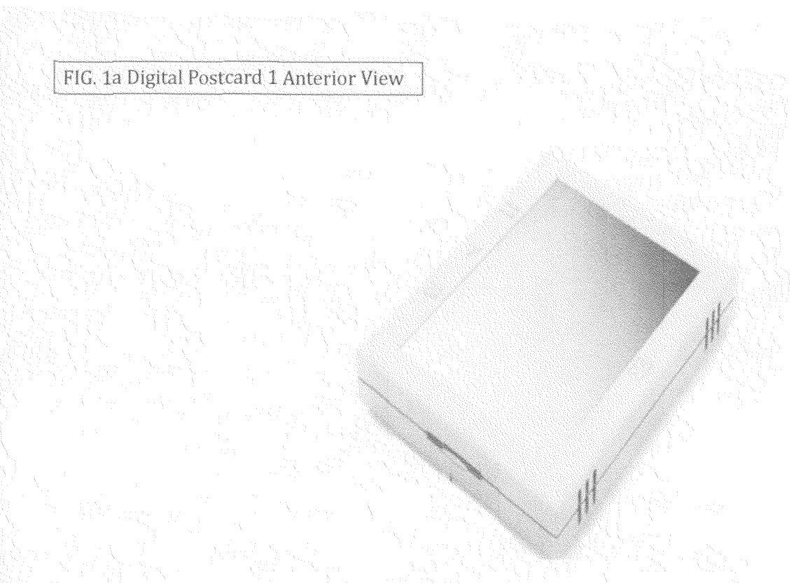

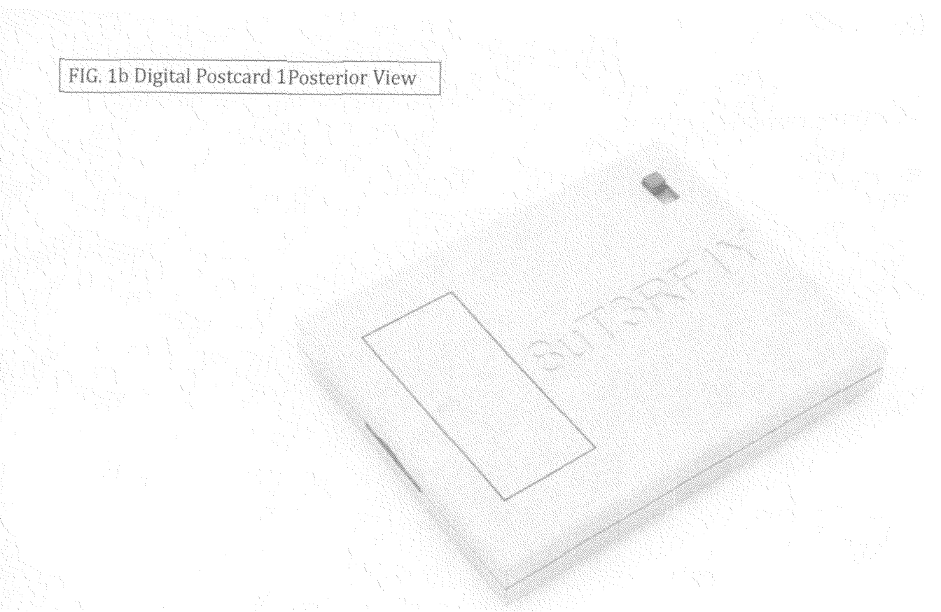

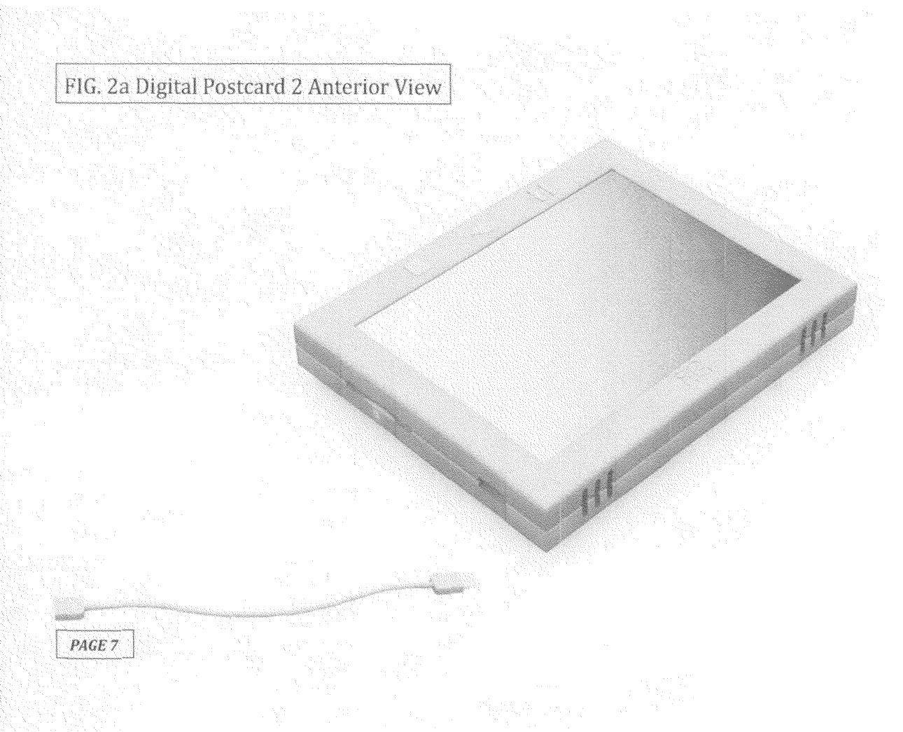

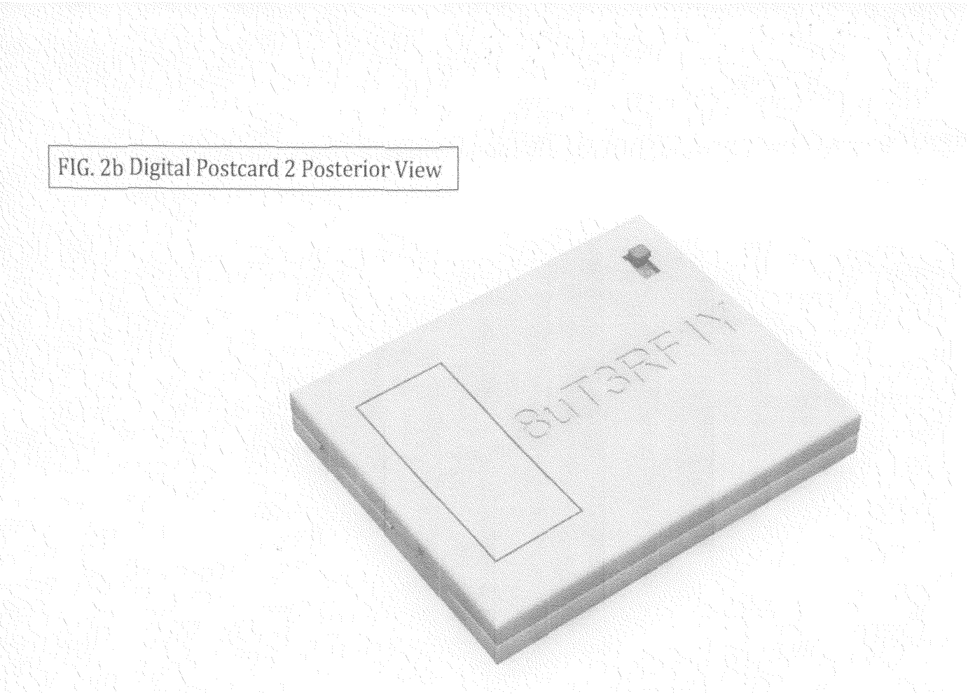

As illustrated in FIGS. 1a, 1b, 2a and 2b, the invention is a digital postcard providing a lightweight postcard-sized electronic device for conveying digitally recorded intimate messages for loved ones far away. Enclosed is one (1) sheet of inventor's disclosure hereby herein incorporated by reference.

The digital postcard of the present invention replicates the dimension of a regular post card. As such it is not only slim, but also light, rectangular in shape and pocket-sized. The digital postcard is available in two (2) different versions; depending on which digital postcard interface, the feature that changes is how the user will load the content onto the device. Both versions (which are referred to as Digital Postcard 1 and Digital Postcard 2) share almost parallel dimensions. Both are 4.25 inches in width, 5.75 inches in length or height, and 0.25 inches in depth. The front display of both models illustrates a wide, full-color liquid crystal display that is illuminated by a powerful light-emitting diode back-light. Located on the lower section of the front display are three (3) control buttons available for directing the operation of the device. Specifically, these navigation buttons are illustrated as Pause Button, Play Button, and Stop Button.

The display screen of the digital postcard is protected by a thin sheet of transparent placed on its surface; the remainder of the body is housed in an injection-molded case constructed with durable material. This casing assists in protecting the device from severe damage, its purpose is for shock absorbency. Speakers, totaling two (2), are located on the top section of the device and are set in recessed depressions with tiny grilles. The speakers are wired to a media processor which provide an avenue for broadcasting audio during a photo slide show and/or video. The power source for the Digital Postcard will be button cell batteries, totaling two (2), which will be concealed in the battery compartment located on the rear side of the unit.

The available media interfaces on the device varies between the Digital Postcard versions. Digital Postcard 1 has a SD Card Port located on the lower right side of the device; SD cards containing media files can be inserted and securely fastened. Digital Postcard 2, contains the same capability but also has a USB port located on the upper right hand side of the device. Additionally, Digital Postcard 2 adds non-volatile on-board memory. This postcard offers users the opportunity to store content directly to the device. This is conducted by delivering the data through USB or SD card.

The Digital Postcard(s) are designed to be used in any situation for the purpose of sending intimate messages to designated individuals. These benefits include multiple digital picture attachments, an integrated slideshow, and full motion video accompanied with audio. The process begins with the purchase of the digital postcard. The target market includes, but not limited to, the elderly, tourists, retail souvenir shops, military personnel, etc. These devices can conceivably be distributed by postal service/delivery means which allows for the primary function of the device—Sending private, intimate messages conveniently and safely without the risk of information being accessed by unauthorized users through online services.

Once the device has been purchased, the user creates the presentation that is desired for the receiver of this gift and uploads the file into the Digital Postcard. A user manual detailing product description, software downloading instruction as well as a user handling and navigation guide will be provided with the device. The software will allow users to edit files in addition to assist saving files in the correct format. As soon as this package is completed to the user's satisfaction, the user will upload the file to the device. If using Digital Postcard 1, the information will need to be uploaded onto the SD Card and inserted to the Digital Postcard SD Card Port for Uploading. If using Digital Postcard 2, the information can either be uploaded through an SD Card following the same procedure for Digital Postcard 1 that was previously outlined or by direct upload through the USB Port. Uploaded information is stored directly to the on-board memory. Once the content is successfully uploaded, the Digital postcard is ready for shipment. Shipping services and conditions are solely the responsibility of the Device owner. Upon receipt of either device, the recipient can activate the presentation and navigate using the three navigation buttons: Play Button, Pause Button, and Stop Button.

The digital postcard offers several distinct advantages over conventional postcards as well as email postcards. The device makes it easy to share abundant amounts of entertaining digit data while maintaining the close intimacy associated with physical touch and engagement. In this manner, the postcard provides a new age style of connecting friends and family with a tradition that has lasted for generations. It transforms the limited capabilities and creates a new market for ingenuity; additionally, it is beneficial to the buyer because it is reusable.

1. I declare that:
a) The information given regarding this invention and elsewhere in support of the invention is correct and,
b) descriptions and illustrations within this application have been explained in the drawings as well as outlined in detail with varying modifications
c) while the invention has been shown, it should be understood by those skilled in the art of equivalent changes in form and detail
d) the scope of the present invention is to be limited only to the claims except as precluded by the prior art
e) the invention which forms the basis of this application has not started and no expenditure has been committed or defrayed, and
f) the invention as disclosed herein may be suitably practiced in the absence of the specific elements of which are disclosed.
g) the substitute specification contains no new matter.
h) the digital postcard substantially as described and illustrated is herein
i) all inventions described and illustrated herein.
